(19) United States
(12) Patent Application Publication
(10) Pub. No.: US 2011/0186970 A1
(43) Pub. Date: Aug. 4, 2011

(54) METHOD FOR MANUFACTURING A SEMICONDUCTOR DEVICE

(75) Inventor: Min Chul SUNG, Seoul (KR)

(73) Assignee: Hynix Semiconductor Inc., Icheon (KR)

(21) Appl. No.: 12/840,184

(22) Filed: Jul. 20, 2010

(30) Foreign Application Priority Data
Feb. 1, 2010 (KR) 10-2010-0009298

(51) Int. Cl. H01L 21/3105; H01L 23/28

(52) U.S. Cl. 257/635; 438/696; 257/E21.241; 257/E23.116

(57) ABSTRACT

A method for manufacturing a semiconductor device comprises: etching a semiconductor substrate to form a plurality of pillars; depositing a first protective film on the sidewalls of the pillar; first etching the semiconductor substrate with the pillar deposited with the first protective film as a mask; forming a first insulating film on the sidewalls of the pillar and the first etched semiconductor substrate; second etching the semiconductor substrate with the pillar including the first insulating film as a mask; forming a second protective film and a second insulating film on the surface of the second etched semiconductor substrate; depositing a barrier film on the sidewalls of the pillar including the second insulating film; and removing the first insulating film, the second insulating film and the barrier film disposed at one sidewall of the pillar to form a contact hole defined by the first protective film and the second protective film.

### CROSS-REFERENCE TO RELATED APPLICATION

The priority of Korean patent application No. 10-2010-0009298 filed on Feb. 1, 2010, the disclosure of which is hereby incorporated in its entirety by reference, is claimed.

### BACKGROUND OF THE INVENTION

Embodiments of the present invention relate to a method for manufacturing a semiconductor device, and more specifically, to a method for manufacturing a semiconductor device including a vertical channel transistor.

Due to the increased integration of semiconductor devices, a channel length of a transistor has been gradually reduced. However, the reduction in the channel length of the transistor may cause short channel effects such as a Drain Induced Barrier Lowering (DIBL) phenomenon, a hot carrier effect and a punch-through phenomenon. In order to prevent the short channel effects, various methods have been proposed. Examples of these methods include a method of reducing a depth of a junction region or a method of increasing a channel length by forming a recess in a channel region of the transistor.

However, as the integration density of the semiconductor memory device (specifically DRAM) has edged up to giga bits, the manufacturing of smaller-sized transistors is required. That is, the transistor of the giga-bit DRAM requires a device area of less than 8F2 (F: minimum feature size), and further requires a device area of 4F2. As a result, it is difficult to attain the required device area with the structure of the current plannar transistor having a gate electrode formed on a semiconductor substrate and a junction region formed at both sides of the gate electrode even though the channel length is subject to scaling.

In order to solve this problem, a vertical channel transistor has been suggested. A method for manufacturing a vertical channel transistor is as follows. A cell region of a semiconductor substrate is etched with a given depth by a photo process to form a top pillar and form a spacer that surrounds a sidewall of the top pillar. The exposed semiconductor substrate is further etched with the spacer as an etching mask to form a trench. An isotropic wet etching process is performed on the trench to form a neck pillar that constitutes an integral structure with the top pillar and extends in a vertical direction. The neck pillar is formed to have a narrower width than that of the top pillar.

A gate insulating film and a surrounding gate that includes a conductive film are formed on the outside sidewalls of the neck pillar. An ion-implantation process is performed on the semiconductor substrate adjacent to the surrounding gate to form a bit line impurity region. The semiconductor substrate is etched to the depth separated from the impurity region to form a buried bit line apart from the impurity region. In order to prevent a short between the buried bit lines, the semiconductor substrate is required to be deeply etched.

Subsequent processes are performed in sequence to obtain a semiconductor device having a vertical transistor according to the prior art.

However, the method of etching the semiconductor substrate to separate the buried bit line decreases the integration of the semiconductor device. As a result, it is difficult to sufficiently secure an area required to make an electrical contact with the buried bit line in a subsequent process as the width of the buried bit line becomes smaller.

Also, in order to form a bit line contact with the buried bit line, additional processes would need to be performed, thereby complicating the process and increasing production cost.

### BRIEF SUMMARY OF THE INVENTION

Various embodiments of the invention are directed to providing a method for manufacturing a semiconductor device that comprises A method for manufacturing a semiconductor device, the method comprising: etching a semiconductor substrate to form a first pillar, the first pillar being part of a plurality of pillars formed; depositing a first protective film over first and second sidewalls of the first pillar; performing a first etching step onto the semiconductor substrate using the first pillar and the first protective film as a mask in order to extend a lower portion of the first pillar and define a first extended lower portion of the first pillar; forming a first insulating film over the first and second sidewalls of the first pillar and the first extended lower portion of the first pillar; performing a second etching step onto the semiconductor substrate using the first pillar and the first insulating film as a mask in order to extend a lower portion of the first pillar and define a second extended lower portion of the first pillar; forming a second protective film and a second insulating film over at least the second extended lower portion of the first pillar; depositing a barrier film over the first and second sidewalls of the first pillar including the first and second extended lower portions, the barrier film being deposited over the second insulating film; and removing the first insulating film, the second insulating film and the barrier film provided over the first sidewall of the first pillar to define a contact hole exposing a portion of the first sidewall of the first pillar, the contact hole being defined between the first protective film and the second protective film.

The first protective film and the second protective film include an oxide film, and wherein the first insulating film, the second insulating film and the barrier film provided over the second sidewall remain intact, the second sidewall being at an opposing side of the first sidewall.

A hard mask pattern is disposed over an upper surface of the first pillar. The first insulating film and the second insulating film include a nitride film. The barrier film includes a titanium nitride film.

The barrier film is removed using a method including: forming a sacrificial oxide film having a height lower than that of an upper surface of the first pillar over the semiconductor substrate; depositing a polysilicon layer over the first pillar and the sacrificial oxide film; removing a first portion of the polysilicon layer to expose the barrier film provided proximate the first sidewall of the first pillar; and removing the exposed barrier film.

The sacrificial oxide film includes a SOD film, wherein the barrier film provided proximate the second sidewall of the first pillar remain covered by the polysilicon layer and is not removed when the barrier film proximate the first sidewall is being removed. The removing-a-first-portion-of-the-polysilicon-layer step includes: implanting ions into a second portion of the polysilicon layer without implanting the ions into the first portion of the polysilicon layer; and removing the first polysilicon layer.

The ion-implanting process is performed a plurality of times. The ion-implanting process is performed at an angle ranging from 0° to 30° with respect to an angle orthogonal to the surface of the semiconductor substrate. Further comprising removing the polysilicon layer and the sacrificial oxide film after exposing the barrier film proximate the first sidewall.

The barrier film is removed using a method including: forming a sacrificial oxide film over the semiconductor substrate and the first pillar; remove the sacrificial oxide film to expose the first pillar; forming a mask pattern that exposes the barrier film proximate the first sidewall of the first pillar over an upper surface of the first pillar and an upper surface of the sacrificial oxide film; and removing the barrier film exposed by the mask pattern.

The mask pattern includes an oxide film. Further comprising removing the mask pattern and the sacrificial oxide film after removing the barrier film proximate the first sidewall. The second insulating film is obtained by nitrifying a surface of the second protective film. A depth of the first extended lower portion of the first pillar has a critical dimension of a finally formed contact hole as an etching target.

A method for manufacturing a semiconductor device, the method comprising: etching a semiconductor substrate to form a pillar; forming a first film of first material over first and second sidewalls of the pillar, the first and second sidewalls being on opposing sides of the pillar; etching the semiconductor substrate to extend a lower portion of the pillar and define a first extended portion of the pillar; forming a first film of second material over the first and second sidewalls and the first extended portion; etching the semiconductor substrate to extend a lower portion of the pillar and define a second extended portion of the pillar below the first extended portion; forming a second film of the first material over at least the second extended portion; forming a second film of the second material at least over the second film of the first material; forming a film of third material over the first and second sidewalls of the pillar including the first and second extended portions, the film of the third material being deposited over the second film of the second material; and removing the first film of the second material, the second film of the second material and the film of the third material provided proximate the first sidewall to define a contact hole exposing a portion of the first sidewall of the pillar, the contact hole being defined between the first film of the first material and the second film of the first material.

The first material is oxide and the second material is nitride, and the third material includes titanium nitride. The first film of the second material, the second film of the second material and the film of the third material provided proximate the second sidewall remain intact during the removing step.

A semiconductor device comprising: a pillar formed over a substrate; a first protective film formed at an upper portion of a first sidewall of the pillar; a second protective film formed at an upper portion of a second sidewall of the pillar; a third protective film formed at a lower portion of the first sidewall of the pillar; a first gap defined between the first protective film and the third protective film, the first gap exposing the first sidewall of the pillar; a fourth protective film formed at a lower portion of the second sidewall of the pillar; a second gap defined between the second protective film and the fourth protective film, the second gap exposing the second sidewall of the pillar; and an insulating film formed over the second protective film, the second gap and the fourth protective film.

The insulating film comprises: a first insulating film formed over the second protective film and the second gap; and a second insulating film formed over the fourth protective film.

### BRIEF DESCRIPTION OF THE DRAWINGS

FIGS. 1a to 1l are cross-sectional diagrams illustrating a method for manufacturing a semiconductor device according to an embodiment of the present invention.

FIGS. 2a to 2c are cross-sectional diagrams illustrating a method for manufacturing a semiconductor device according to another embodiment of the present invention.

### DESCRIPTION OF EMBODIMENTS

The present invention will be described in detail with reference to the attached drawings.

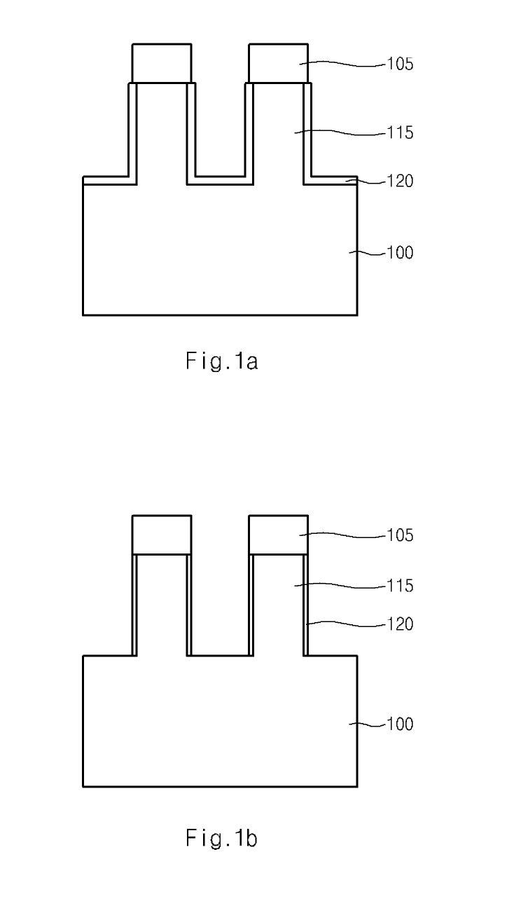

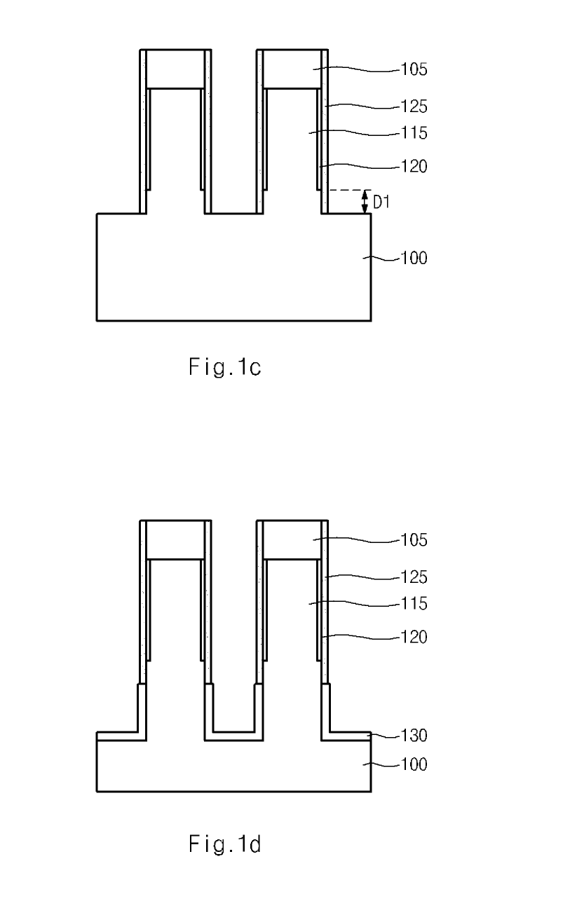

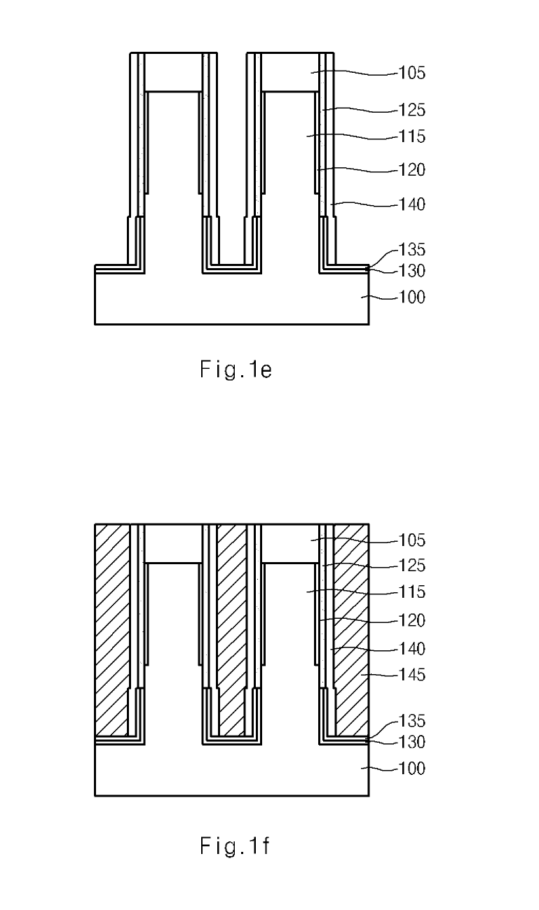

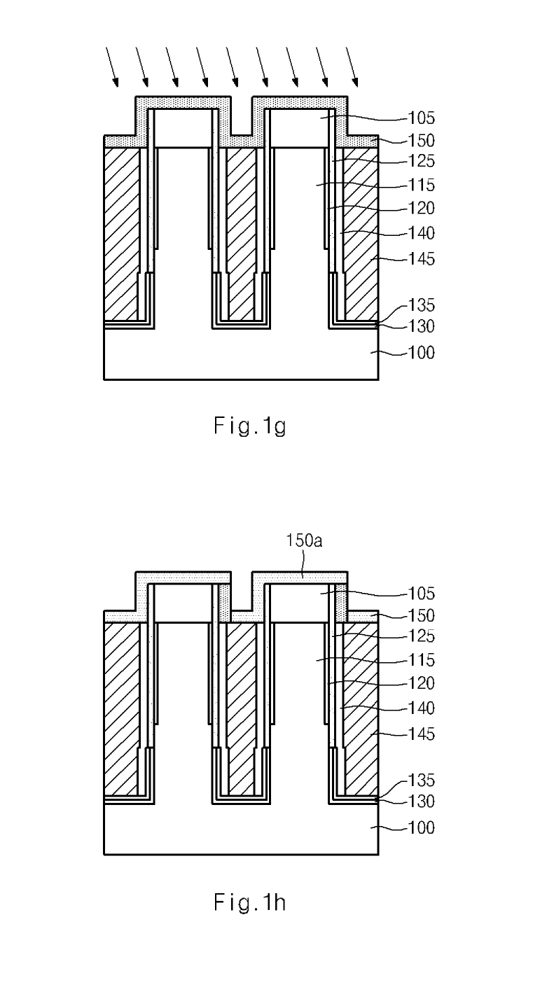

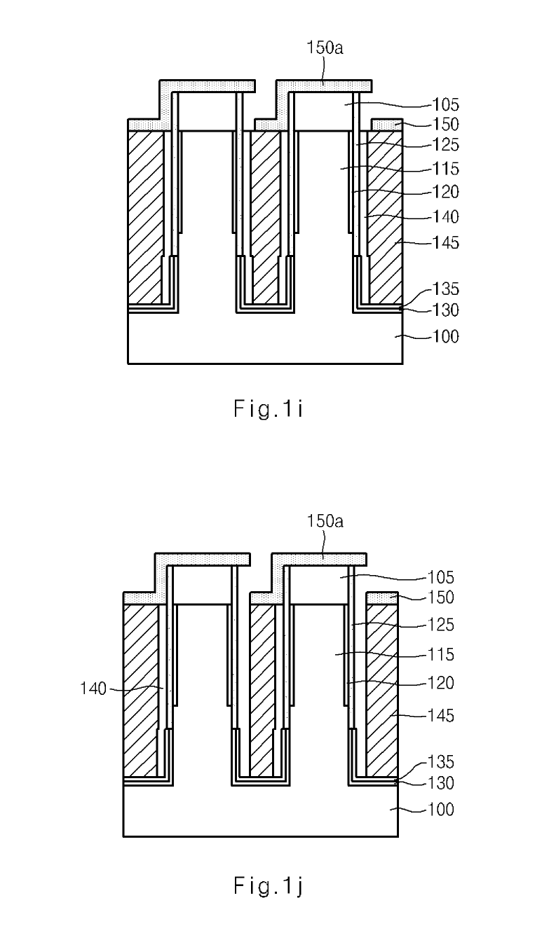

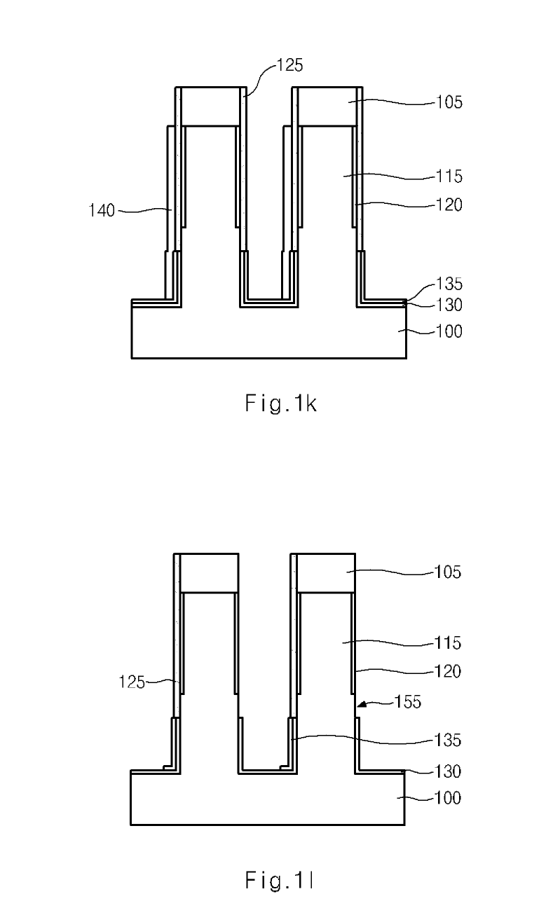

FIGS. 1a to 1l are cross-sectional diagrams illustrating a method for manufacturing a semiconductor device according to an embodiment of the present invention.

Referring to FIG. 1a, a hard mask layer (not shown) and an anti-reflection film (not shown) are formed on an upper portion of a semiconductor substrate 100. The hard mask layer (not shown) can be formed of an amorphous-carbon layer, a silicon oxide nitride (SiON) film, an amorphous silicon layer or a combination thereof.

A photoresist pattern (not shown) that defines a buried bit line region is formed on the upper portion of the anti-reflection film (not shown). The photoresist pattern (not shown) is formed in a line pattern.

The anti-reflection film (not shown) and the hard mask layer (not shown) are etched with a photoresist pattern (not shown) as a mask. The photoresist pattern (not shown) and the etched anti-reflection film (not shown) are removed to form a hard mask pattern 105 that defines a buried bit line region.

The semiconductor substrate 100 is etched with the hard mask pattern 105 as a mask to form a plurality of pillars 115. A portion of the semiconductor substrate 100 is etched to form the pillar 115 in a vertical direction.

An oxidation process is performed to form a first oxide film 120 on the surface of the semiconductor substrate 100 including the pillar 115. This process is performed to protect the semiconductor substrate 100 and the pillar 115. A portion of the first oxide film 120 can be formed on the inside surface of the semiconductor substrate 100 (e.g., sidewalls of the pillar 115). For example, when the first oxide film 120 is formed 100 Å thick, an oxide film of about 50 Å is deposited on the surface of the semiconductor substrate 100 and formed on the inside of the semiconductor substrate 100.

Referring to FIG. 1b, an etch-back process is performed to remove the first oxide film 120 formed over the semiconductor substrate 100 and over the top surface of the pillar 115, while leaving the first oxide film 120 on the sidewalls of the pillar 115. In the etch-back process, the first oxide film 120 deposited on the surface of the semiconductor substrate 100 is etched with the hard mask pattern 105 as a mask. After the etch-back process, the first oxide film 120 that remains on the sidewalls of the pillar 115 becomes thinner than the original thickness.

Referring to FIG. 1c, the semiconductor substrate 100 is further etched by a depth D1 using the hard mask pattern 105 and the pillar 115 as a mask.

A liner nitride film 125 is formed on the sidewalls of the pillar 115 and the hard mask pattern 105. The liner nitride film 125 is obtained by performing an etch-back process after a nitride film is formed on the entire surface of the semiconductor substrate 100 including the hard mask pattern 105 and the pillar 115. The liner nitride film 125 is formed to protect the exposed contact hole region.

Referring to FIG. 1d, the semiconductor substrate 100 is further etched with the hard mask pattern 105 and the liner nitride film 125 as a mask. An oxidation process is performed to form a second oxide film 130 on the surface of the semiconductor substrate 100. Like the first oxide film 120 shown in FIG. 1a, the second oxide film 130 deposited is partially formed on the inside of the semiconductor substrate 100 and partially on the surface of the semiconductor substrate 100.

Referring to FIG. 1e, a plasma nitrifying process is performed to transform the surface of the second oxide film 130 into a nitride film 135. The nitride film 135 is deposited on the second oxide film 130.

A barrier film 140 is formed on the sidewalls of the pillar 115 and the hard mask pattern 105. The barrier film 140 is formed with a material having an etching selectivity difference with the nitride film 135 (e.g., titanium nitride (TiN)). The barrier film 140 is formed by performing an etch-back process after a titanium nitride film is deposited on the resultant surface including the hard mask pattern 105 and the pillar 115.

Referring to FIG. 1f, a sacrificial oxide film 145 is formed on the resultant surface of the semiconductor substrate 100 including the barrier film 140. The sacrificial oxide film 145 includes a Spin On Dielectric (SOD) oxide film.

After a chemical mechanical polishing (CMP) process is performed to expose the hard mask pattern 105, an annealing process or a curing process are performed.

The sacrificial oxide film 145 is recessed so that the hard mask pattern 105 is protruded toward an upper portion of the sacrificial oxide film 145. The process for recessing the sacrificial oxide film 145 is performed by a wet, a dry or an etch-back process.

Referring to FIG. 1g, the exposed barrier film 140 by the recessed sacrificial oxide film 145 is removed. That is, the barrier film 140 formed on the sidewalls of the hard mask pattern 105 is removed to expose the liner nitride film 125. A polysilicon layer 150 is deposited on the top surface of the sacrificial oxide film 145 and over the hard mask pattern 105. Since the sacrificial oxide film 145 and the hard mask pattern 105 are formed with a step difference from each other and the polysilicon layer 150 is formed of a lining pattern, the polysilicon layer is also formed with a step difference. That is, the polysilicon layer is formed of an upper planar surface formed over the sacrificial oxide film 145 and a lower planar surface formed over the hard mask pattern 105 with a step difference from the upper planar surface, a first sidewall formed over one sidewall of the hard mask pattern 105 and a second sidewall formed over the other sidewall of the hard mask 105. The first and the second sidewalls of the polysilicon layer 150 are bridging the upper planar surface and the lower planar surface, respectively.

Referring to FIG. 1h, a BF₂ ion is implanted into a portion of the polysilicon layer 150. The ion-implantation is performed by way of a slant implantation. The ion-implantation is performed twice, including a first implantation with a first angle and the second implantation with a second angle different from the first angle. The implantation angles ranging from 0 to 30° with respect to an angle orthogonal to the surface of the semiconductor substrate 100. In an embodiment, the first angle is orthogonal to the surface of the semiconductor substrate 100 and the second angle ranging from 20 to 30° with respect to an angle orthogonal to the surface of the semiconductor substrate 100. During the slant implantation, the ions are implanted into the top portion of the hard mask pattern 105, the upper and lower planar surface of the polysilicon layer 150a and the first sidewall of the polysilicon layer 150a, but not implanted into the second sidewall of the polysilicon layer 150.

Referring to FIG. 1i, a cleaning process is performed to remove the second sidewall the polysilicon layer 150 where the ion is not implanted. When the second sidewall of the polysilicon layer 150 is removed the barrier film 140 formed between the pillar 115 and one sidewall of the sacrificial oxide film 145 is exposed. However, the barrier film 140 formed between the pillar 115 and the other sidewall of the sacrificial oxide film 145 is not exposed.

Referring to FIG. 1j, the barrier film 140 formed at one sidewall of the pillar 115 is removed. However, the barrier film formed at the other sidewall of the sacrificial oxide film 145 remains.

Referring to FIG. 1k, the ion-implanted polysilicon layer 150a and the sacrificial oxide film 145 are removed. The liner nitride film 125 is exposed on one sidewall of the pillar 115, and the barrier film 140 is exposed on the other sidewall of the pillar 115.

Referring to FIG. 1l, the nitride film 135 not covered by the barrier film 140 and remains on the other sidewall of the pillar 115 is removed. The liner nitride film 125 exposed on the one sidewall of the pillar 115 is removed to expose the pillar 115 between the first oxide film 120 and the second oxide film 130. The barrier film 140 that remains on the other sidewall of the pillar 115 is removed. However, the liner nitride film 125 formed at the other sidewall of the pillar 115 is not removed but remains. The exposed pillar 115 is a contact hole 155.

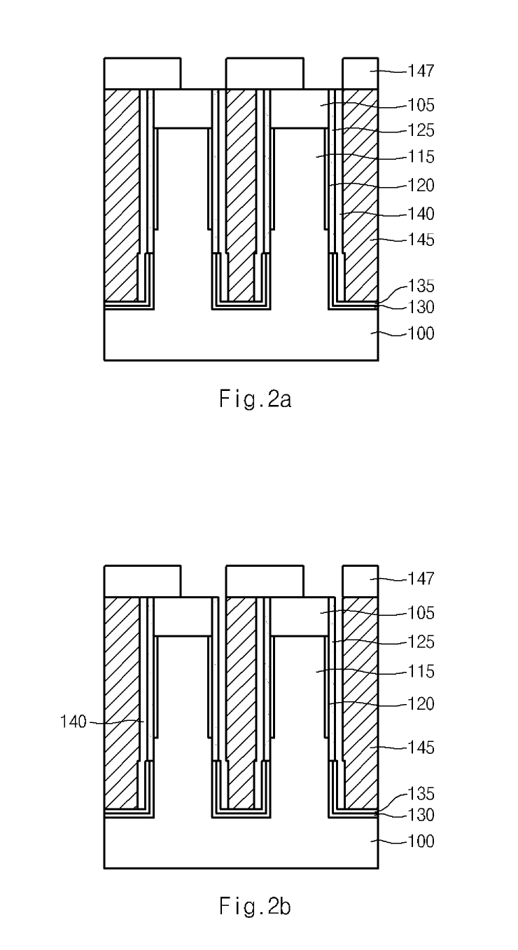

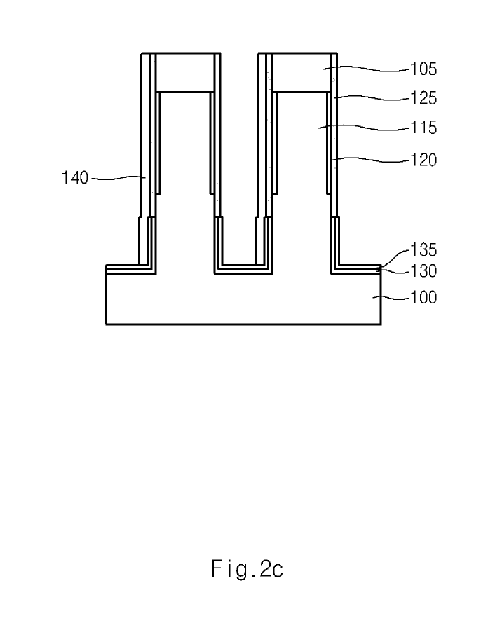

FIGS. 2a to 2c are cross-sectional diagrams illustrating a method for manufacturing a semiconductor device according to another embodiment of the present invention.

First, the processes made in FIGS. 1a-1f are performed in the same manner. Then, as shown in FIG. 2a, an oxide film (not shown) and a photoresist pattern (not shown) are formed on the upper portion of the pillar 115 and the sacrificial oxide film 145. The oxide film (not shown) is etched with the photoresist pattern (not shown) to form a mask pattern 147. The mask pattern 147 is formed to expose the barrier film 140 formed on one sidewall of the pillar 115. The photoresist pattern (not shown) is removed.

Referring to FIG. 2b, the barrier film 140 disposed at one sidewall of the pillar 115 exposed by the mask pattern 147 is removed to expose the liner nitride film 125 and the nitride film 135.

Referring to FIG. 2c, a wet etching process is performed to remove the mask pattern 147 and the sacrificial oxide film 145. Thereafter, the processes shown in FIGS. 11 is identically performed to form a contact hole.

The width of the contact hole 155 is determined by the etch depth ‘D1’ onto the semiconductor substrate 100 performed in the step shown in FIG. 1C. The etch depth D1 can be more precisely controllable under a given critical dimension rather than a process forming a contact hole using a photolithography process. Accordingly, the critical dimension CD uniformity of the contact hole can be improved. The contact hole is electrically coupled to, for example, a buried bit line pattern formed over the contact hole. As described above, the embodiments of the present invention can reduce the process steps in the formation of the contact hole and form the contact hole at a precise location with a more uniform critical dimension. A step difference between a silicon layer of the region including the contact hole and a peripheral oxide film can be minimized to improve a step coverage characteristic in a subsequent process for depositing a metal layer.

The above embodiments of the present invention are illustrative and not (imitative. Various alternatives and equivalents are possible. The invention is not limited by the type of deposition, etching polishing, and patterning steps describe herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A method for manufacturing a semiconductor device, the method comprising:
etching a semiconductor substrate to form a first pillar, the first pillar being part of a plurality of pillars formed;
depositing a first protective film over first and second sidewalls of the first pillar;
performing a first etching step onto the semiconductor substrate using the first pillar and the first protective film as a mask in order to extend a lower portion of the first pillar and define a first extended lower portion of the first pillar;
forming a first insulating film over the first and second sidewalls of the first pillar and the first extended lower portion of the first pillar;
performing a second etching step onto the semiconductor substrate using the first pillar and the first insulating film as a mask in order to extend a lower portion of the first pillar and define a second extended lower portion of the first pillar;
forming a second protective film and a second insulating film over at least the second extended lower portion of the first pillar;
depositing a barrier film over the first and second sidewalls of the first pillar including the first and second extended lower portions, the barrier film being deposited over the second insulating film; and
removing the first insulating film, the second insulating film and the barrier film provided over the first sidewall of the first pillar to define a contact hole exposing a portion of the first sidewall of the first pillar, the contact hole being defined between the first protective film and the second protective film.

2. The method according to claim 1, wherein the first protective film and the second protective film include an oxide film, and
wherein the first insulating film, the second insulating film and the barrier film provided over the second sidewall remain intact, the second sidewall being at an opposing side of the first sidewall.

3. The method according to claim 1, wherein a hard mask pattern is disposed over an upper surface of the first pillar.

4. The method according to claim 1, wherein the first insulating film and the second insulating film include a nitride film.

5. The method according to claim 1, wherein the barrier film includes a titanium nitride film.

6. The method according to claim 1, wherein the barrier film is removed using a method including:
forming a sacrificial oxide film having a height lower than that of an upper surface of the first pillar over the semiconductor substrate;
depositing a polysilicon layer over the first pillar and the sacrificial oxide film;
removing a first portion of the polysilicon layer to expose the barrier film provided proximate the first sidewall of the first pillar; and
removing the exposed barrier film.

7. The method according to claim 6, wherein the sacrificial oxide film includes a SOD film,
wherein the barrier film provided proximate the second sidewall of the first pillar remain covered by the polysilicon layer and is not removed when the barrier film proximate the first sidewall is being removed.

8. The method according to claim 6, wherein the removing-a-first-portion-of-the-polysilicon-layer step includes:
implanting ions into a second portion of the polysilicon layer without implanting the ions into the first portion of the polysilicon layer; and
removing the first polysilicon layer.

9. The method according to claim 8, wherein the ion-implanting process is performed a plurality of times.

10. The method according to claim 8, wherein the ion-implanting process is performed at an angle ranging from 0° to 30° with respect to an angle orthogonal to the surface of the semiconductor substrate.

11. The method according to claim 6, further comprising removing the polysilicon layer and the sacrificial oxide film after exposing the barrier film proximate the first sidewall.

12. The method according to claim 1, wherein the barrier film is removed using a method including:
forming a sacrificial oxide film over the semiconductor substrate and the first pillar;
remove the sacrificial oxide film to expose the first pillar;
forming a mask pattern that exposes the barrier film proximate the first sidewall of the first pillar over an upper surface of the first pillar and an upper surface of the sacrificial oxide film; and
removing the barrier film exposed by the mask pattern.

13. The method according to claim 12, wherein the mask pattern includes an oxide film.

14. The method according to claim 12, further comprising removing the mask pattern and the sacrificial oxide film after removing the barrier film proximate the first sidewall.

15. The method according to claim 1, wherein the second insulating film is obtained by nitrifying a surface of the second protective film.

16. The method according to claim 1, wherein a depth of the first extended lower portion of the first pillar has a critical dimension of a finally formed contact hole as an etching target.

17. A method for manufacturing a semiconductor device, the method comprising:
etching a semiconductor substrate to form a pillar;
forming a first film of first material over first and second sidewalls of the pillar, the first and second sidewalls being on opposing sides of the pillar;
etching the semiconductor substrate to extend a lower portion of the pillar and define a first extended portion of the pillar;
forming a first film of second material over the first and second sidewalls and the first extended portion;
etching the semiconductor substrate to extend a lower portion of the pillar and define a second extended portion of the pillar below the first extended portion;
forming a second film of the first material over at least the second extended portion;
forming a second film of the second material at least over the second film of the first material;
forming a film of third material over the first and second sidewalls of the pillar including the first and second extended portions, the film of the third material being deposited over the second film of the second material; and
removing the first film of the second material, the second film of the second material and the film of the third material provided proximate the first sidewall to define a contact hole exposing a portion of the first sidewall of the pillar, the contact hole being defined between the first film of the first material and the second film of the first material.

18. The method according to claim 17, wherein the first material is oxide and the second material is nitride, and the third material includes titanium nitride.

19. The method of claim 17, wherein the first film of the second material, the second film of the second material and the film of the third material provided proximate the second sidewall remain intact during the removing step.

20. A semiconductor device comprising:
a pillar formed over a substrate;
a first protective film formed at an upper portion of a first sidewall of the pillar;
a second protective film formed at an upper portion of a second sidewall of the pillar;
a third protective film formed at a lower portion of the first sidewall of the pillar;
a first gap defined between the first protective film and the third protective film, the first gap exposing the first sidewall of the pillar;
a fourth protective film formed at a lower portion of the second sidewall of the pillar;
a second gap defined between the second protective film and the fourth protective film, the second gap exposing the second sidewall of the pillar; and
an insulating film formed over the second protective film, the second gap and the fourth protective film.

21. The semiconductor device according to claim 20, wherein the insulating film comprises:
a first insulating film formed over the second protective film and the second gap; and
a second insulating film formed over the fourth protective film.
